(19) United States
(12) Patent Application Publication
(10) Pub. No.: US 2007/0210705 A1
(43) Pub. Date: Sep. 13, 2007

(54) Organic electroluminescent element and manufacturing method of an organic electroluminescent element and a display

(76) Inventors: Hajime Yokoi, Tokyo (JP); Ryo Shoda, Tokyo (JP); Yuko Abe, Tokyo (JP); Eiichi Kitazume, Tokyo (JP)

Correspondence Address: SQUIRE, SANDERS & DEMPSEY L.L.P., 1 MARITIME PLAZA, SUITE 300, SAN FRANCISCO, CA, 94111, US

(21) Appl. No.: 11/657,967

(22) Filed: Jan. 24, 2007

(30) Foreign Application Priority Data
Mar. 9, 2006 (JP) 2006-064175
May 23, 2006 (JP) 2006-142563

(51) Int. Cl. H01L 51/50

(52) U.S. Cl. 313/506; 428/690; 428/917; 313/504; 427/66

(57) ABSTRACT

One embodiment of the present invention is an organic electroluminescent element including a first electrode, a second electrode, an organic luminescent medium layer including an organic luminescent layer and one or more other layer, wherein the first electrode faces the second electrode, wherein the organic luminescent medium layer is between the first electrode and the second electrode, and wherein an inorganic barrier layer is between the organic luminescent medium layer.

### CROSS REFERENCE

This application claims priority to Japanese application number 2006-64175, filed on Mar. 9, 2006, and priority to Japanese application number 2006-142563, filed on May 23, 2006, which are incorporated herein by reference.

### BACKGROUND OF THE INVENTION

1. Field of the Invention

The present invention is related to an organic electroluminescent device using an electroluminescent phenomenon of an organic thin film, and a manufacturing method of an organic electroluminescent element and display unit.

2. Description of the Related Art

An organic electroluminescent element has an organic luminescent layer presenting an electroluminescent phenomenon between an anode and a cathode. When a voltage is applied between the electrodes, holes and electrons are poured into an organic luminescent layer. Then holes and electrons recombine in an organic luminescent layer. And an organic luminescent layer emits light. In other words an organic electroluminescent element is a self-luminous element.

To improve luminous efficiency, a hole injection layer, a hole transport layer, an electron transport layer and an electron injection layer are further installed appropriately. A hole injection layer and a hole transport layer are installed between an anode and an organic luminescent layer. An electron transport layer and an electron injection layer are installed between an organic luminescent layer and a cathode. An organic luminescent layer, a hole injection layer, a hole transport layer, an electron transport layer and an electron injection layer can be referred to as an organic luminescent medium layer.

These organic luminescent medium layers comprise a low molecular material or a polymeric material. Examples of low molecular materials are described below. Copper phthalocyanine (CuPc) is used as a hole injection layer. N,N′-diphenyl-N,N′-bis(3-methylphenyl)-1,1′-biphenyl-4,4′diamine (TPD) is used as a hole transport layer. Tris(8-quinolinol) aluminium (Alq3) is used as an organic luminescent layer. 2-(4-biphenylyl)-5-(4-tert-butyl-phenyl)-1,3,4,-oxadiazole (PBD) is used as an electron transport layer. Lithium fluoride (LiF) is used as an electron injection layer.

Generally thickness of each layer of the organic luminescent medium layers comprising a low molecular material is from 0.1 to 200 nm. These layers are formed by a dry process in a vacuum condition such as a vacuum evaporation method such as the resistance heating method or sputter method.

And there are various kinds of low molecular materials. Improvement of luminous efficiency, emission brightness, life time or the like by combining the various materials is expected.

On the other hand, for example, for polymeric materials, the following materials for organic luminescent layers can be used: The material which low-molecular luminescent coloring matter dissolves in polymers such as polystyrene, polymethyl methacrylate and polyvinyl carbazole; Macromolecular fluorescent substance such as polyphenylene vinylene derivative (PPV) or poly alkylfluorene derivative (PAF); and Polymer phosphor such as rare earth metal system.

Generally ink is made by dissolving these polymeric materials in a solvent. And, using wet process such as application or printing, a layer of which thickness is about 1-100 nm is formed.

In comparison with a dry process in a vacuum condition such as a vacuum evaporation method, a wet process has the following merit: Film formation under atmospheric air is possible; facilities are inexpensive; upsizing is easy; and a layer can be formed efficiently in a short time.

In addition, an organic thin film layered using a polymeric material has the following merit: Crystallization and cohesion are hard to occur; and a pinhole and a foreign matter of the other layer can be coated. Therefore, an organic thin film made of a polymeric material can prevent defectiveness such as a short-circuit or a dark spot.

From the above-mentioned reason, combination/laminating of the following two layers are highly effectual measures: the organic luminescent medium layer which is formed using a low molecular material by dry process in a vacuum condition; and the organic luminescent medium layer which is formed using a polymeric material by wet process in atmospheric air.

In other words an organic electroluminescent element of arbitrary size, high luminous efficiency, high emission brightness and long life without defect can be manufactured efficiently.

However, when an organic luminescent medium layer is formed in vacuum condition on an organic luminescent medium layer formed in atmospheric air, the following problem occurs: Deteriorating factor such as O₂, O₃ or H₂O adsorbed on the surface of an organic luminescent medium layer which is formed in atmospheric air reacts with an organic luminescent medium layer material which is formed in vacuum condition; and a display characteristic such as luminous efficiency, emission brightness or life time degrades.

In other words there is little quantity of deteriorating factor adsorbed in the surface of each layer when an organic luminescent medium layer is laminated only by dry process in a vacuum condition. Therefore, harmful effect is little.

After having layered in atmospheric air by wet process, a different organic luminescent medium layer is layered by dry process in a vacuum condition. In that case, the following problem occurs: Deteriorating factor adsorbed in the surface of an organic luminescent medium layer in wet process reacts with an organic luminescent medium layer material layered by dry process. Therefore, degradation of a display characteristic may be caused.

Especially, a case where an electron injection layer is formed using alkaline earth metal by a dry process in a vacuum condition is described below. Alkaline earth metal is easy to react with deteriorating factor. Therefore, a composition of alkaline earth metal changes when an alkaline earth metal is layered in the surface of an organic luminescent medium layer adsorbing deteriorating factor. Therefore, substantial film thickness of an alkaline earth metal part changes. As a result, a layer of a desired energy level is not obtained. Therefore, electron transfer is disturbed. Carrier balance is changed. Luminous efficiency and emission brightness fall.

As a method to solve the above mentioned problem of a deteriorating factor such as O₂, O₃ or H₂O, wet process under inert atmosphere is reported. Japanese Patent Laid-Open No. 2002-352954.

However, it is necessary to introduce a large-scaled inert atmosphere apparatus when a large-sized display is manufactured in a wet process by this method. Therefore, the cost is high. In addition, working efficiency and accuracy fall.

In addition, it is proposed that a dielectric organic barrier layer is formed, JP-T 2005-510851. However, in case when an organic barrier layer is used, one part of an organic barrier layer is decomposed because an organic barrier layer reacts with deteriorating factor. Therefore, a barrier function falls.

In addition, as mentioned above, each layer of an organic luminescent medium layer is a thin film. Therefore, it is necessary to secure planarity of each layer. Especially, planarity of the surface of ITO used as an electrode is bad. Therefore, planarity is achieved by applying a hole injection polymeric material to the ITO surface. E Express, Mar. 1, 2004, page 38-44.

Especially, a mixture of poly (3,4-ethylenedioxy thiophen) and polystyrene sulfonate (PEDOT-PSS), and polyaniline (PANI) to which ionic dopant is added are widely used Japanese Patent Laid-Open No. 2003-338379 or JP-T 2003-536228.

Because the above mentioned materials use ionic dopant, the conductivity improves. As mentioned above, it is highly effective for improvement of planarity of an organic electroluminescent element and improvement of device characteristic to use PEDOT-PSS and PANI for a hole injection layer.

### (The First Problem)

The present invention provides an organic electroluminescent element of high luminous efficiency, high emission brightness and long life, without defect. And the organic electroluminescent element is protected from influence of deteriorating factor. In addition, the present invention provides an efficient manufacturing method of an inexpensive organic electroluminescent element of high luminous efficiency, high emission brightness and long life, without defects. And the method is protected from influence of deteriorating factors.

Additionally, the present invention provides an inexpensive display of high luminous efficiency, high emission brightness and long life, without defects. And the display is protected from influence of deteriorating factors.

### (The Second Problem)

When the above mentioned PEDOT-PSS and PANI are used for a hole injection layer, these ionic components are scattered in an organic thin film. In addition, even if a charge (hole) injection layer does not include an ionic component at first, an ionic component may be generated by electrolysis of a charge (hole) injection layer. In addition, these ionic components pass a luminescent layer, and they are scattered to a surface boundary of a cathode. It is pointed out that the ion component hurts a characteristic of an element 2003, Toray research center poster session VI-2 or Organic electroluminescent panel discussion (2005), page 35-36.

When a material containing an ionic dopant such as PEDOT-PSS and PANI is used for a hole injection layer in the present invention, deterioration of device characteristic due to the ion component does not occur.

### SUMMARY OF THE INVENTION

One embodiment of the present invention is an organic electroluminescent element including a first electrode, a second electrode, an organic luminescent medium layer including an organic luminescent layer and one or more other layers, wherein the first electrode faces the second electrode, wherein the organic luminescent medium layer is between the first electrode and the second electrode, and wherein an inorganic barrier layer is between the organic luminescent medium layer.

### BRIEF DESCRIPTION OF DRAWINGS

FIG. 1 is an explanatory drawing which shows an example of an organic electroluminescent element of the present invention.

FIG. 2 is an explanatory drawing which shows an example of an organic electroluminescent element of the present invention.

FIG. 3 is an explanatory drawing which shows an example of an organic electroluminescent element of the present invention.

FIG. 4 is an explanatory drawing which shows an example of letterpress printing machine used for the present invention.

FIG. 5 is an explanatory drawing which shows an example of a display of the present invention.

FIG. 6 is a sectional drawing which shows an organic electroluminescent element of one embodiment of the present invention.

In these drawings, 1 is a translucent substrate; 2 is a transparent first electrode layer; 3 is an organic luminescent medium layer; 4 is an organic hole injection layer; 5 is an ion blocking barrier layer; 6 is a hole transport layer; 7 is an organic luminescent layer; 8 is an electron injection layer; 9 is a cathode layer as a second electrode; 101 and 301 each are a substrate; 102 and 302 each are a first electrode; 103 and 303 each are an organic luminescent medium layer; 103a and 303a each are a hole injection layer; 103b and 303b each are a hole transport layer; 103c and 303c each are an organic luminescent layer; 103d and 303d each are an electron injection layer; 104 and 304 each are an inorganic barrier layer; 105 and 305 each are a second electrode; 306 is an insulator layer; 201 is a substrate; 202 is an ink tank; 203 is an ink chamber; 204 is an anilox roll; 204a is an ink layer; 205 is a plate; 206 is a printing cylinder; and 207 is a flat base.

### DESCRIPTION OF THE PREFERRED EMBODIMENTS

The first embodiment of the present invention is explained using drawings as follows. In addition, the present invention is not limited to this embodiment.

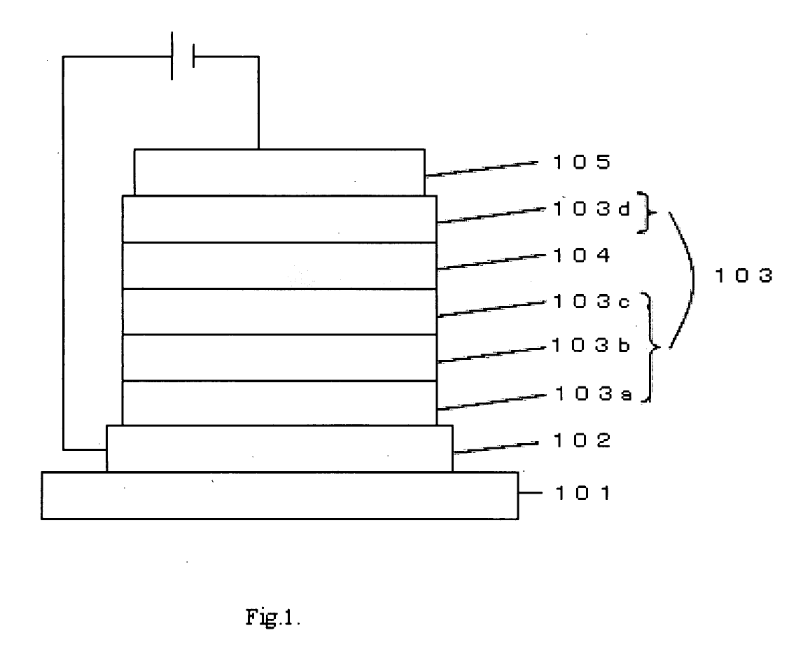

FIG. 1 is a sectional schematic view of an example of an organic electroluminescent element of the present invention.

When the substrate side is the display side, for substrate 101, a translucent substrate having strength of a certain degree can be used. For example, a glass substrate and a plastic film or sheet can be used. If a thin glass substrate of thickness from 0.2 to 1.0 mm is used, a thin organic electroluminescent element having very high barrier property can be obtained.

A first electrode 102 preferably is made from a transparent or semitransparent conductive material.

When first electrode 102 is an anode, for example, a complex oxide (ITO) of indium and tin, complex oxide (IZO) of indium and zinc, tin oxide, zinc oxide, indium oxide or zinc aluminium complex oxide can be used.

ITO can be preferably used from the following reasons: Electrical resistance is low; Solvent resistance is high; and transparency is high.

ITO can be layered by evaporation or a sputtering method on substrate 101.

In addition, first electrode 102 can be formed by a Coating-Pyrolysis Process.

For example, after applying precursors such as octylic acid indium or acetone indium on substrate 101, oxide is formed by thermal decomposition.

Or metal such as aluminium, gold or silver can be vapor-deposited translucent.

Or organic semiconductor such as polyaniline can be used.

First electrode 102 can be patterned by etching if necessary. In addition, the surface of first electrode 102 can be activated by UV processing or plasma treatment.

Organic luminescent medium layer 103 is selected from plural functional layers. For example, for a functional layer, a hole injection layer, a hole transport layer, an organic luminescent layer, a hole blocking layer, an electron transport layer, an electron injection layer and an insulator layer are exemplified.

Organic luminescent medium layer 103 had better have an organic luminescent layer and other one or more functional layer(s) to obtain sufficient luminous efficiency, emission brightness and life time.

And inorganic barrier layer 104 is formed between the laminated organic luminescent medium layers.

Deteriorating factor is adsorbed in the surface of an organic luminescent medium layer formed before formation of inorganic barrier layer 104. So an organic luminescent medium layer formed after formation of inorganic barrier layer 104 does not deteriorate.

In FIG. 1, hole injection layer 103a, hole transport layer 103b, organic luminescent layer 103c and electron injection layer 103d are selected as organic luminescent medium layer 103. However, layer structure can be selected arbitrarily.

In addition, in FIG. 1, there is inorganic barrier layer 104 between organic luminescent layer 103c and electron injection layer 103d. However, there may be an inorganic barrier layer 104 between any layers. Besides, there may be plural barrier layers between any layers respectively.

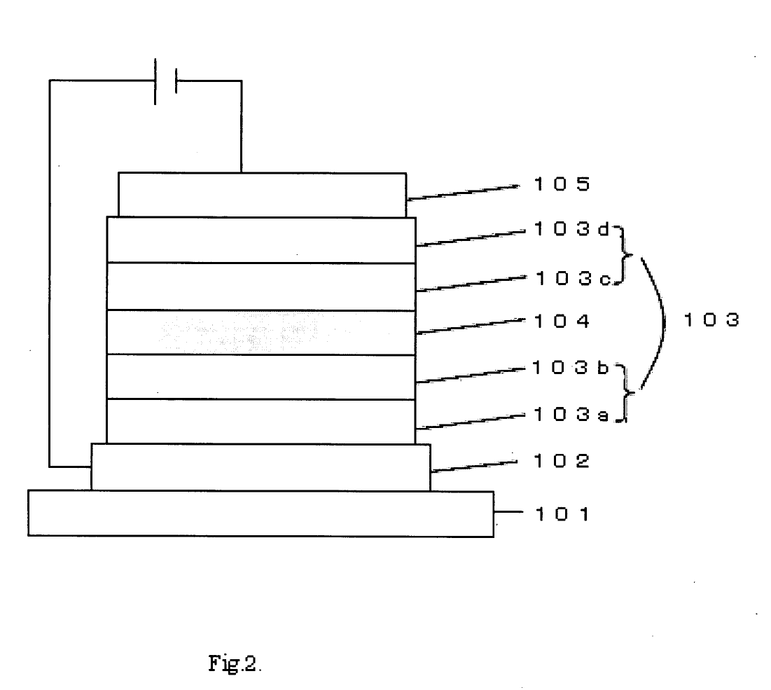

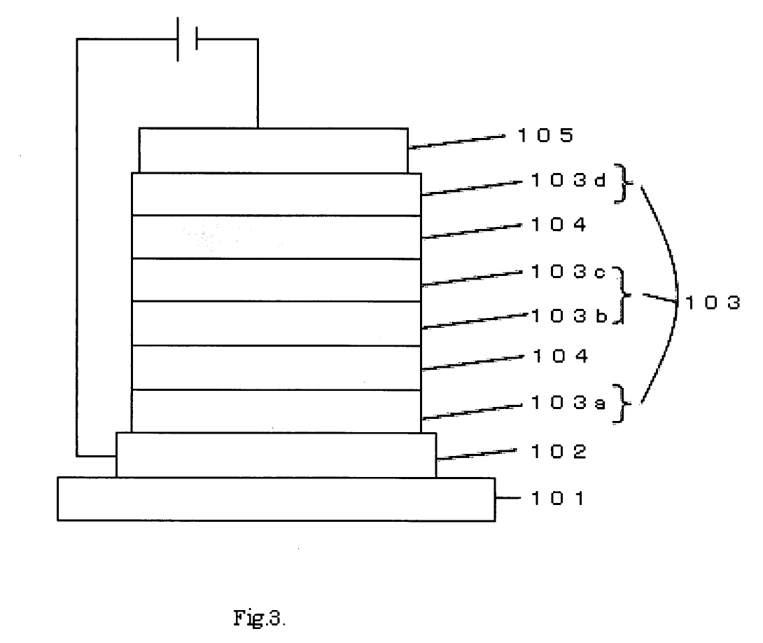

In FIG. 2, there is inorganic barrier layer 104 between hole transport layer 103b and organic luminescent layer 103c. In FIG. 3, there are inorganic barrier layers 104 between hole injection layer 103a and hole transport layer 103b and between organic luminescent layer 103c and electron injection layer 103d.

For a hole injecting material and a hole transport material used for a hole injection layer and a hole transport layer, the material which is generally employed as hole transport material can be preferably used.

For example, copper phthalocyanine and the derivative, aromatic amine system such as 1,1-bis (4-di-p-tolylamino phenyl) cyclohexane, N,N′-diphenyl-N, N′-bis (3-methylphenyl)-1,1′-biphenyl-4,4′diamine (TPD) and triphenylamines can be used for low molecular material.

Film formation is possible by dry process in a vacuum condition such as vacuum evaporation method using these materials.

In addition, hole injection ink and hole transport ink can be made by dispersing and/or dissolving these materials in solvents such as toluene, xylene, acetone, anisole, methyl anisole, dimethylanisole, benzoic ether, methyl benzoate, mesitylene, Tetralin, amyl benzene, methyl ethyl ketone, methyl isobutyl ketone, cyclohexanone, methanol, ethanol, isopropanol, ethyl acetate, butyl acetate, cyclohexanol or water. In addition, mixed solvent can be used.

Film formation is possible by wet process under an atmospheric air using these inks.

In addition, as polymeric material, polyaniline, polythiophene, polyvinyl carbazole, a mixture of poly (3,4-ethylenedioxy thiophen) and polystyrene sulfonate, PPV derivative or PAF derivative can be used.

Hole injection ink and hole transport ink can be made by dispersing and/or dissolving these hole injection materials and hole transport materials in solvents such as toluene, xylene, acetone, methyl ethyl ketone, methyl isobutyl ketone, cyclohexanone, methanol, ethanol, isopropanol, ethyl acetate, butyl acetate, cyclohexanol and water. In addition, mixed solvent can be used.

Film formation is possible by wet process under an atmospheric air using these inks.

As an organic luminescent material used for an organic luminescent layer, material generally used as an organic luminescent material can be preferably used.

For example, as well-known fluorescent low molecular material which can emit light from singlet state, coumarin system, perylene system, a pyran system, anthrone system, a porphyrin system, quinacridon system, N,N′-dialkyl permutation quinacridon system, naphthalimido system and N,N′-diaryl permutation pyrrolo pyrrole series can be used.

In addition, well-known rare earth metal complex system phosphorescence low molecular material which can emit light from a triplet state can be used.

As for these materials, film formation is possible by dry process in a vacuum condition such as vacuum evaporation method.

In addition, organic luminescent ink can be made by dispersing and/or dissolving these materials in a solvent such as toluene, xylene, acetone, anisole, methyl anisole, dimethylanisole, benzoic ether, methyl benzoate, mesitylene, Tetralin, amyl benzene, methyl ethyl ketone, methyl isobutyl ketone, cyclohexanone, methanol, ethanol, isopropanol, ethyl acetate, butyl acetate, cyclohexanol and water. In addition, mixed solvent can be used.

Film formation by a wet process in an atmospheric air using this ink is possible.

In addition, as polymeric material, the material which fluorescent coloring matter such as coumarin system, perylene system, a pyran system, anthrone system, a porphyrin system, quinacridon system, N,N′-dialkyl permutation quinacridon system, naphthalimido system and N,N′-diaryl permutation pyrrolo pyrrole series dissolves in polymeric material such as polystyrene, polymethyl methacrylate or polyvinyl carbazole can be used.

In addition, polymer luminous bodies such as a macromolecular fluorescene body such as PPV system and PAF system or a polymer phosphorescence luminous body including a rare earth metal complex can be used.

An organic luminescent ink can be made by dispersing and/or dissolving these polymeric materials in solvent such as toluene, xylene, acetone, anisole, methyl anisole, dimethylanisole, benzoic ether, methyl benzoate, mesitylene, Tetralin, amyl benzene, methyl ethyl ketone, methyl isobutyl ketone, cyclohexanone, methanol, ethanol, isopropanol, ethyl acetate, butyl acetate, cyclohexanol and water. In addition, mixed solvent can be used a

Film formation by a wet process in an atmospheric air using this ink is possible.

An aromatic system solvent such as toluene, xylene, anisole, methyl anisole, dimethylanisole, benzoic ether, methyl benzoate, mesitylene, Tetralin and amyl benzene is especially desirable from the following reasons: Solubility of polymeric material is good; and the handling is easy.

As the electron injection layer, alkaline earth metals, alkali metal such as lithium fluoride or lithium oxide, or salt or oxide of alkaline earth metals are preferably used.

As for these materials, film formation by dry process in a vacuum condition such as vacuum deposition is possible.

Thickness of each layer of the organic luminescent medium layer is arbitrary. However, it is preferable for the thickness to be 0.1-200 nm.

On the other hand, for a barrier material used for an inorganic barrier layer, the material which is hard to react with a deteriorating factor is preferable.

As a material having the above mentioned character, an insulating material or a semi-conductor comprising oxide, nitride and fluoride, or the metal of which a work function is equal to or more than 4.0 eV is preferred.

For example, an inorganic barrier layer comprising SiOₓ, SiO₂, SiNₓ, Si₃N₄, AlF₃, CaF₂, MnF₂, Ag, Cr, Cu, Ge, Ir, Ni, Os, Pd, Pt, Re, Rh, Ru, Se, Si, Te and W and the like can be layered by dry process such as vacuum evaporation methods such as resistance heating evaporation method in a vacuum condition, an eletron beam method, a sputtering method or a CVD method such as plasma CVD technique.

When the metal of which work function is equal to or more than 4.0eV and which is hard to be oxidized is used as an inorganic barrier layer, reaction with deteriorating factor can be prevented effectively.

When an inorganic barrier layer is too thick, hole and electron transfer are disturbed, and light emission is obstructed. In addition, a basic characteristic of the organic light emission medium layer cannot be obtained.

In addition, a barrier effect cannot be obtained sufficiently when inorganic barrier layer is too thin.

Therefore, it is preferable for the film thickness to be less than 1.0 nm more than 0.1 nm. More preferably, it is 0.2 nm-0.5 nm.

When the second electrode 105 is a cathode, the following materials can be used: A simple metal substance such as Mg, Al or Yb; and alloy system of low work function metal and stable metal which can balance electron injection efficiency and stability (for example, alloys such as MgAg, AlLi or CuLi.).

As for the formation method of a cathode, depending on the material, vacuum evaporation methods such as a resistance heating evaporation method, an eletron beam method or a sputtering method can be used.

It is preferable for the thickness of a cathode to be about 10 nm-1,000 nm.

In FIG. 1, an anode is laminated on substrate 101 first. However, a cathode can be laminated on substrate 101 first.

In addition, in FIG. 1, the substrate side is the display side. However, the opposite side of the substrate side may be the display side.

After having formed one or more layers of an organic luminescent medium layer by wet process in atmospheric air, the barrier layer is formed. The other organic luminescent medium layer is formed by dry process in a vacuum condition afterwards. Then an inexpensive organic electroluminescent element having high luminous efficiency, high emission brightness and long life without defect can be manufactured efficiently.

A manufacturing method of an organic electroluminescent element shown in FIG. 1 is explained below.

When the substrate side is the display side, for substrate 101, translucent substrate having strength of a certain degree can be used. For example, a glass substrate and a plastic film or sheet can be used. If a thin glass substrate of which thickness is 0.2-1.0 mm is used, a thin organic electroluminescent element of which barrier property is very high can be manufactured.

As a formation material of first electrode 102, transparent or semitransparent conductive material is preferably used.

When first electrode 102 is an anode, for example, complex oxide (ITO) of indium and tin, complex oxide (IZO) of indium and zinc, tin oxide, zinc oxide, indium oxide or zinc aluminium complex oxide can be used.

ITO can be preferably used from the following reason: Electrical resistance is low; Solvent resistance is high; and Transparency is high.

ITO can be layered by evaporation or a sputtering method on substrate 101.

In addition, first electrode 102 can be formed by an Coating-Pyrolysis Process.

For example, after applying precursors such as octylic acid indium or acetone indium on substrate 101, oxide is formed by thermal decomposition.

Or metal such as aluminium, gold or silver can be vapor-deposited translucent.

Or organic semiconductor such as polyaniline can be used.

First electrode 102 can be patterned by etching if necessary. In addition, the surface of first electrode 102 can be activated by UV processing or plasma treatment.

Organic luminescent medium layer 103 is selected from plural functional layers. For example, for a functional layer, a hole injection layer, a hole transport layer, an organic luminescent layer, a hole blocking layer, an electron transport layer, an electron injection layer and an insulator layer are exemplified.

Organic luminescent medium layer 103 had better have an organic luminescent layer and other one or more functional layer(s) to obtain sufficient luminous efficiency, emission brightness and life time.

And barrier layer such as inorganic barrier layer 104 is formed between the laminated organic luminescent medium layers.

Deteriorating factor is adsorbed in the surface of an organic luminescent medium layer formed before barrier layer formation. So an organic luminescent medium layer formed after barrier layer formation does not deteriorate.

In FIG. 1, hole injection layer 103a, hole transport layer 103b, organic luminescent layer 103c and electron injection layer 103d are selected as organic luminescent medium layer 103. However, layer structure can be selected arbitrarily.

In addition, in FIG. 1, there is a barrier layer between organic luminescent layer 103c and electron injection layer 103d. However, there may be a barrier layer between any layers. Besides, there may be plural barrier layers between any layers respectively.

In FIG. 2, there is a barrier layer between hole transport layer 103b and organic luminescent layer 103c. In FIG. 3, there are barrier layers between hole injection layer 103a and hole transport layer 103b and between organic luminescent layer 103c and electron injection layer 103d.

For a hole injecting material and a hole transport material used for a hole injection layer and a hole transport layer, the material which is generally employed as hole transport material can be preferably used.

For example, copper phthalocyanine and the derivative, aromatic amine system such as 1,1-bis (4-di-p-tolylamino phenyl) cyclohexane, N,N′-diphenyl-N, N′-bis (3-methylphenyl)-1,1′-biphenyl-4,4′diamine (TPD) and triphenylamines can be used for low molecular material.

Film formation is possible by dry process in a vacuum condition such as vacuum evaporation method using these materials.

In addition, hole injection ink and hole transport ink can be made by dispersing these materials in solvents such as toluene, xylene, acetone, anisole, methyl anisole, dimethylanisole, benzoic ether, methyl benzoate, mesitylene, Tetralin, amyl benzene, methyl ethyl ketone, methyl isobutyl ketone, cyclohexanone, methanol, ethanol, isopropanol, ethyl acetate, butyl acetate, cyclohexanol or water. In addition, mixed solvent can be used.

Film formation is possible by wet process under an atmospheric air using these inks.

In addition, as polymeric material, polyaniline, polythiophene, polyvinyl carbazole, a mixture of poly (3,4-ethylenedioxy thiophen) and polystyrene sulfonate, PPV derivative or PAF derivative can be used.

Hole injection ink and hole transport ink can be made by dispersing these hole injection materials and hole transport materials in solvents such as toluene, xylene, acetone, methyl ethyl ketone, methyl isobutyl ketone, cyclohexanone, methanol, ethanol, isopropanol, ethyl acetate, butyl acetate, cyclohexanol and water. In addition, mixed solvent can be used.

Film formation is possible by wet process under an atmospheric air using these inks.

As an organic luminescent material used for an organic luminescent layer, a material generally employed as an organic luminescent material can be preferably used.

For example, a well-known fluorescent low molecular material which can emit light from singlet state, coumarin system, perylene system, a pyran system, anthrone system, a porphyrin system, quinacridon system, N,N′-dialkyl permutation quinacridon system, naphthalimido system and N,N′-diaryl permutation pyrrolo pyrrole series can be used.

In addition, a well-known rare earth metal complex system phosphorescence low molecular material which can emit light from a triplet state can be used.

As for these materials, film formation is possible by dry process in a vacuum condition such as vacuum evaporation method.

In addition, an organic luminescent ink can be made by dispersing these materials in a solvent such as toluene, xylene, acetone, anisole, methyl anisole, dimethylanisole, benzoic ether, methyl benzoate, mesitylene, Tetralin, amyl benzene, methyl ethyl ketone, methyl isobutyl ketone, cyclohexanone, methanol, ethanol, isopropanol, ethyl acetate, butyl acetate, cyclohexanol and water. In addition, mixed solvent can be used.

Film formation by a wet process in an atmospheric air using this ink is possible.

In addition, as a polymeric material, the material which fluorescent coloring matter such as coumarin system, perylene system, a pyran system, anthrone system, a porphyrin system, quinacridon system, N,N′-dialkyl permutation quinacridon system, naphthalimido system and N,N′-diaryl permutation pyrrolo pyrrole series dissolves in polymeric material such as polystyrene, polymethyl methacrylate or polyvinyl carbazole can be used.

In addition, polymer luminous bodies such as a macromolecular fluorescene body such as PPV system and PAF system or a polymer phosphorescence luminous body including a rare earth metal complex can be used.

An organic luminescent ink can be made by dispersing these polymeric materials in solvent such as toluene, xylene, acetone, anisole, methyl anisole, dimethylanisole, benzoic ether, methyl benzoate, mesitylene, Tetralin, amyl benzene, methyl ethyl ketone, methyl isobutyl ketone, cyclohexanone, methanol, ethanol, isopropanol, ethyl acetate, butyl acetate, cyclohexanol and water. In addition, mixed solvent can be used.

Film formation by a wet process in an atmospheric air using this ink is possible.

Aromatic system solvent such as toluene, xylene, anisole, methyl anisole, dimethylanisole, benzoic ether, methyl benzoate, mesitylene, Tetralin and amyl benzene is especially desirable from the following reasons: Solubility of polymeric material is good; and the handling is easy.

As the electron injection layer, alkaline earth metals, alkali metal such as lithium fluoride or lithium oxide, or salt or oxide of alkaline earth metals can be preferably used.

As for these materials, film formation by dry process in a vacuum condition such as vacuum deposition is possible.

Thickness of each layer of the organic luminescent medium layer is arbitrary. However, it is preferable for the thickness to be 0.1-200nm.

A barrier material generally used for a barrier layer can be preferably used.

However, by the decomposition of an organic barrier material when an organic barrier layer reacts with a deteriorating factor on some layer, a barrier function may fall.

Therefore, the inorganic barrier layer which can prevent this degradation should be used.

As a material having the above mentioned character, an insulating material or a semi-conductor comprising oxide, nitride and fluoride, or the metal of which a work function is equal to or more than 4.0 eV is preferred.

For example, a barrier layer comprising SiOₓ, SiO₂, SiNₓ, Si₃N₄, AlF₃, CaF₂, MnF₂, Ag, Cr, Cu, Ge, Ir, Ni, Os, Pd, Pt, Re, Rh, Ru, Se, Si, Te and W and the like can be layered by dry process such as vacuum evaporation methods such as resistance heating evaporation method in a vacuum condition, an eletron beam method, a sputtering method or a CVD method such as plasma CVD technique.

When the metal of which work function is equal to or more than 4.0eV and which is hard to be oxidized is used as a barrier layer, reaction with deteriorating factor can be prevented effectively.

When a barrier layer is too thick, hole and electron transfer are disturbed, and light emission is obstructed. In addition, a basic characteristic of the organic light emission medium layer cannot be obtained.

In addition, a barrier effect cannot be obtained sufficiently when a barrier layer is too thin.

Therefore, it is preferable for the film thickness to be less than 1.0 nm more than 0.1 nm. More preferably, it is 0.2 nm-0.5 nm.

When the second electrode 105 is a cathode, the following materials can be used: Metal simple substance such as Mg, Al or Yb; and alloy system of low work function metal and stable metal which can balance electron injection efficiency and stability (for example, alloys such as MgAg, AlLi or CuLi.).

As for the formation method of a cathode, depending on the material, vacuum evaporation methods such as a resistance heating evaporation method, an eletron beam method or a sputtering method can be used.

It is preferable for the thickness of a cathode to be about 10 nm-1,000 nm.

In FIG. 1, an anode is laminated on substrate 101 first. However, a cathode can be laminated on substrate 101 first.

In addition, in FIG. 1, substrate 101 side is the display side. However, opposite side of substrate 101 side may be the display side.

There is an application method or a printing method for the above mentioned wet process. There is method to use a spin coater, a bar coater, a roll coater, a die coater or a gravure coater for an application method.

However, it is difficult to form pattern by these application methods directly. On the other hand, pattern can be formed directly and easily by a printing method.

Therefore, well-known printing methods such as letterpress printing, intaglio printing method, screen printing, gravure printing method, flexographic printing method or offset printing can be preferably used when an organic luminescent medium layer is layered by wet process.

Especially letterpress printing is suitable for manufacturing an organic electroluminescent element from the following reasons: In the viscosity range that a viscosity characteristic of ink is good, it can be printed without damaging substrate; and utilizing efficiency of ink material is good.

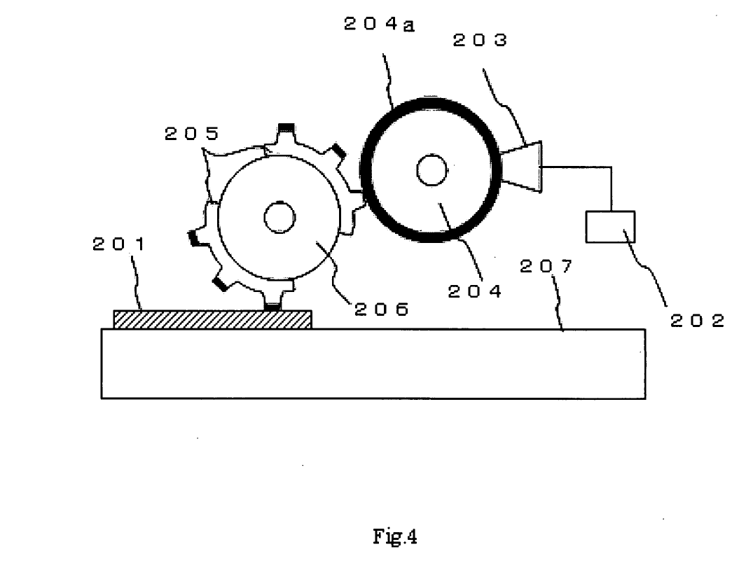

An example of a letterpress printing machine used for the present invention is shown in FIG. 4. An ink comprising a material of the organic luminescent medium layer is pattern-printed on substrate 201 on which an electrode is formed.

A letterpress printing machine has ink tank 202, ink chamber 203, anilox roll 204 and printing cylinder 206 which plate 205 is mounted on. An ink comprising a material of the organic luminescent medium layer is accommodated in ink tank 202. The ink is sent into ink chamber 203 from ink tank 202. In addition, anilox roll 204 is supported rotatably close against an ink supply of ink chamber 203.

Ink layer 204a supplied on the anilox roll surface becomes uniform in thickness by a rotation of anilox roll 204. When this ink layer 204a approaches anilox roll 204, ink layer 204a transfers in projection parts of plate 205 mounted on rotationally driven printing cylinder 206.

In addition, substrate 201 is transported to a printing position of flat base 207 by unillustrated transporting means. And ink in projection parts of plate 205 is printed on substrate 201. The ink is dried if necessary.

An organic luminescent medium layer can be preferably layered on substrate 201 in this way.

A well-known plate can be preferably used for plate 205. However, light-sensitive resin relief printing plate is especially preferable.

As light-sensitive resin relief printing plate, there is the following relief printing plate; a solvent developing type relief printing plate (developer for an exposed resin is an organic solvent.); and a water-developable relief printing plate (developer is water.). A solvent developing type relief printing plate has resistance to water type ink. A water-developable relief printing plate has resistance to organic solvent system ink. Depending on the characteristic of ink comprising material of the organic luminescent medium layer, relief printing plate can be selected from solvent developing type and water developing type.

For example, an organic electroluminescent element shown in FIG. 1 can be made by the following method: Hole injection layer 103a, hole transport layer 103b and organic luminescent layer 103c are formed by letterpress printing in atmospheric air; inorganic barrier layer 104 is formed in a vacuum condition afterwards; and electron injection layer 103d is formed in a vacuum condition afterwards.

In addition, an organic electroluminescent element can be formed by the following method: Hole injection layer 103a and hole transport layer 103b are formed in vacuum; Organic luminescent layer 103c is formed by letterpress printing in atmospheric air next; Inorganic barrier layer 104 is formed in a vacuum condition next; and Electron injection layer 103d is formed in a vacuum condition next.

In other words, by a preferred combination of organic luminescent medium layer formation in a vacuum condition and an organic luminescent medium layer formation in the atmospheric air, an organic electroluminescent element can be manufactured.

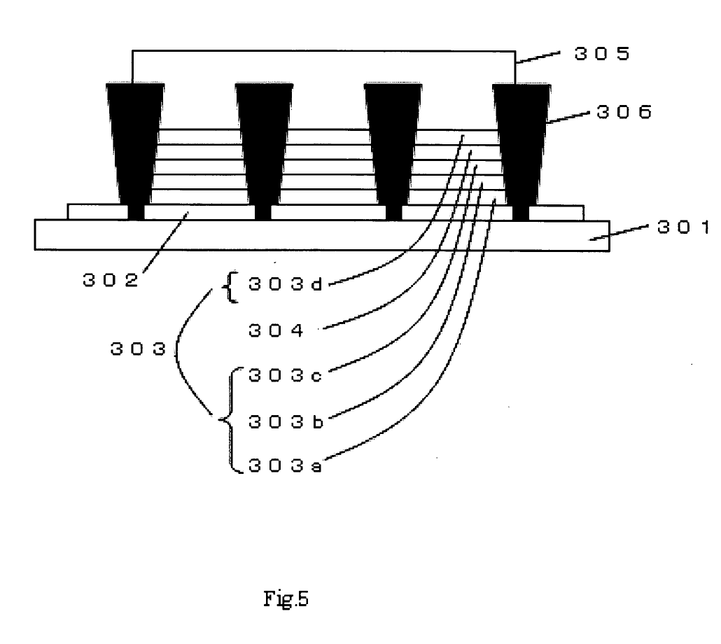

An example of display unit of passive matrix type with the use of an organic electroluminescent element of the present invention is shown in FIG. 5 next. FIG. 5 is a sectional schematic view.

When substrate 301 side is the display side, line-shaped transparent or semitransparent first electrode 302 is formed on substrate 301 as an anode. Insulator layer 306 can be formed between adjacent electrodes if necessary next. For example, insulator layer 306 can be formed by a well-known method such as photo-lithography methods using a photosensitive material.

Spreading of ink comprising material of an organic luminescent medium layer can be controlled by insulator layer 306 between adjacent electrodes.

For a photosensitive material forming insulator layer 306, positive type resist or negative type resist can be used. For example, for material having insulating properties, materials such as a polyimide system, an acryl resin system or a novolac resin system can be used.

In addition, a photosensitive material may contain a material of light shielding properties to improve a display characteristic of an organic electroluminescent element. Besides, a photosensitive material may contain liquid-repellent material to prevent ink spreading to an insulator layer.

A light-sensitive resin for insulator layer 306 can be applied by an application method using spin coater, bar coater, roll coater, die coater or gravure coater. An applied light-sensitive resin can be patterned by a photo-lithography method.

When spin coater is used, film of desired thickness may not be obtained by applying ink one time. In that case, by repeating a similar process multiple times, film of desired thickness can be obtained.

The surface of insulator layer 306 can be made liquid repellent by performing processing such as plasma cleaning or UV cleaning on obtained insulator layer 306 if necessary.

For example, hole injection layer 303a, hole transport layer 303b and organic luminescent layer 303c are layered by letterpress printing in an atmospheric air after forming insulator layer 306.

As a barrier layer, inorganic barrier layer 304 is formed in vacuum next. Electron injection layer 303d is layered in vacuum next.

As shown in FIG. 5, organic luminescent medium layer 303 includes hole injection layer 303a, hole transport layer 303b, organic luminescent layer 303c and electron injection layer 303d. However, layer structure can be selected arbitrarily.

In addition, in FIG. 5, there is inorganic barrier layer 304 as barrier layer between organic luminescent layer 303c and electron injection layer 303d.

However, there may be inorganic barrier layer 304 between arbitrary layers. Besides, there may be plural barrier layer between any layers respectively.

In example of FIG. 5, hole injection layer 303a, hole transport layer 303b and organic luminescent layer 303c are formed in atmospheric air.

However, the following formation method can be used: Hole injection layer 303a and hole transport layer 303b are formed in vacuum; next organic luminescent layer 303c is formed by letterpress printing in atmospheric air; as a barrier layer, inorganic barrier layer 304 is then formed in vacuum; and electron injection layer 303d is formed in vacuum afterwards.

In other words an organic luminescent medium layer can be manufactured by a preferred combination of formation of an organic luminescent medium layer in the vacuum and formation of an organic luminescent medium layer in the atmospheric air.

And the second line-shaped electrode 305 (a cathode) can be formed to be perpendicular to first electrode 302.

In FIG. 5, an anode is laminated on substrate 301. However, a cathode may be laminated on substrate 301.

In addition, in FIG. 5, substrate 301 side is the display side. However, opposite side of substrate 301 side may be display side.

In addition, in FIG. 5, display unit of passive matrix type drive system using line electrode is illustrated. However, well-known drive system such as segment type using arbitrary pattern electrode and active matrix type using pixel electrodes and thin film transistor can be used.

In addition, if necessary, an organic electroluminescent element is sealed using glass cap and adhesive to protect the organic electroluminescent element from outside oxygen and moisture.

Display unit can be made in this way.

When a substrate is flexible, a display unit can be made by sealing using a sealing compound and a flex film.

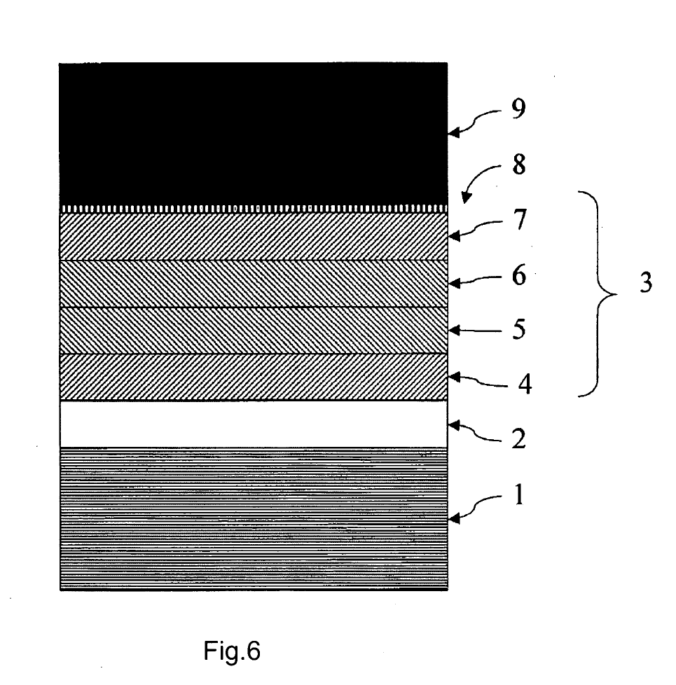

The second embodiment of the present invention is explained using a drawing in detail. FIG. 6 is a sectional drawing showing an example of an organic electroluminescent element.

As mentioned above, a thin film made of an inorganic material is much finer than thin film made of an organic substance. Therefore, even if impurity can pass an inter-molecular gap of an organic compound, impurity cannot pass film comprising an inorganic material.

Thus, in the present embodiment, a thin layer comprising an inorganic material is installed between a hole injection layer and an organic luminescent layer.

As shown in FIG. 6, an organic electroluminescent element has transparent substrate 1, transparent first electrode layer 2, organic luminescent medium layer 3 (organic hole injection layer 4, ion blocking barrier layer 5, hole transport layer 6, organic luminescent layer 7, electron injection layer 8) and the second electrode (cathode layers 9).

In addition, organic luminescent medium layer 3 has an organic charge injection layer, an ion blocking barrier layer and an organic luminescent layer mainly.

However, structure of organic luminescent medium layer 3 is not limited to this structure.

Organic luminescent medium layer 3 may have plural layers such as a charge transport layer or a charge blocking layer. In addition, thickness of each layer is arbitrary. However, preferably thickness of each layer is from 0.1 nm to 100 nm. It is preferable for total film thickness of organic luminescent medium layer 3 to be 100 nm-1,000 nm.

At first, for transparent substrate 1, a transparent substrate having strength of a certain degree can be used. For example, a glass substrate and a plastic film or sheet can be used.

For example, if a thin glass substrate of which thickness is 0.2 mm-1 mm is used, a thin organic electroluminescent element of which barrier property is very high can be made.

In addition, if a flexible plastic film is used, manufacturing of an organic electroluminescent element by taking-up is possible. In other words an inexpensive element can be provided.

For a plastic film, polyethylene terephthalate, polypropylene, cyclo-olefin polymers, polyamide, polyether sulfone, polymethyl methacrylate and polycarbonate can be used.

In addition, if a ceramic evaporation film and gas barrier property films such as polyvinylidene chloride, polyvinyl chloride or saponified ethylene-vinyl acetate copolymer are laminated on a substrate side where transparent first electrode 2 is not formed, barrier property improves.

In other words the organic electroluminescent element of which life time is long can be made.

In addition, for a material of transparent first electrode layer 2, the conductive material which is a material of transparent or semitransparent electrode can be used.

For example, complex oxide (ITO) of indium and tin can be used preferably.

In addition, this transparent first electrode layer 2 can be formed by an evaporation method or a sputtering method on transparent substrate 1.

In addition, this transparent first electrode layer 2 can be formed by an Coating-Pyrolysis Process. For example, precursors such as octylic acid indium or acetone indium are applied on substrate. Oxide is formed by thermal decomposition next.

Or an electrode which metal such as aluminium, gold or silver is vapor-deposited translucent on a substrate can be used. In addition, transparent first electrode layer 2 may be patterned by etching if necessary. In addition, the surface of first electrode layer 2 may be activated by UV processing or plasma treatment.

Organic luminescent medium layer 3 is described below.

Organic hole injection layer 4 is placed in the upper part of transparent first electrode layer 2. Organic hole injection layer 4 is a layer which pours hole from transparent first electrode layer 2 into organic luminescent layer 7 side.

For a material used for this layer, the following material can be used because the conductivity is high: A mixture (PEDOT-PSS) of poly (3,4-ethylenedioxy thiophen) and polystyrene sulfonate of which conductivity is improved by using ionic dopant; and Polyaniline (PANI) to which ionic dopant is added.

Ion blocking barrier layer 5 is a layer preventing a material from scattering from transparent first electrode layer 2 and/or organic hole injection layer 4 to organic luminescent layer 7. This material is indium in ITO or a sodium ion or a sulfate ion occurring from PEDOT-PSS.

Detailed mechanism is not understood definitely, but it is found that these materials hurt luminous efficiency and a life time of an organic electroluminescent element when these material mixes with organic luminescent layer 7.

For material used for ion blocking barrier layer 5, inorganic materials such as inorganic oxide, inorganic nitride, complex oxide including transition metals and metal can be used. These inorganic materials can be formed by a vacuum evaporation method, CVD method, a sputtering method or a sol-gel process.

In addition, for oxide used here, oxide of chromium (Cr), molybdenum (Mo), tungsten (W), vanadium (V), niobium (Nb), tantalum (Ta), titanium (Ti), zirconium (Zr), hafnium (Ht), scandium (Sc), yttrium (lateral), thorium (Tr), manganese (Mn), iron (Fe), ruthenium (Ru), osmium (Os), cobalt (Co), nickel (Ni), copper (Cu), zinc (Zn), cadmium (Cd), aluminium (Al), gallium (Ga), indium (In), silicon (Si), Ge, tin (Sn), plumbum (Pb), antimony (Sb), bismuth (Bi) or so-called rare-earth element from lanthanum (La) to lutetium (Lu) can be illustrated.

In addition, for nitride used here, gallium nitride (GaN), indium nitride (InN), aluminum nitride (AlN), boron nitride (BN), a silicon nitride (SiN), magnesium nitride (MgN), molybdenum nitride (MoN), calcium nitride (CaN), niobium nitride (NbN), tantalum nitride (TaN), vanadium nitride (BaN), nitriding zinc (ZnN), zirconium nitride (ZrN), iron nitride (FeN), copper nitride (CuN), barium nitride (BaN), nitriding lanthanum (LaN), chromium nitride (CrN), nitriding yttrium (YN), lithium nitride (LiN), titanium nitride (TiN) and these composite nitride can be illustrated.

In addition, for complex oxide including transition metals used here, barium titanate (BaTiO₃), strontium titanate (SrTiO₃), calcium titanate (CaTiO₃), potassium niobate (KNbO₃), bismuth iron oxide (BiFeO₃), lithium niobate (lithium niobate), sodium vanadate (Na₃VO₄), vanadic acid iron (FeVO₃), titanic acid vanadium (TiVO₃), chromic acid vanadium (CrVO₃), vanadic acid nickel (NiVO₃), vanadic acid magnesium (MgVO₃), vanadic acid calcium (CaVO₃), vanadic acid lanthanum (LaVO₃), molybdic acid vanadium (VMoO₅), molybdic acid vanadium (V₂MoO₈), vanadic acid lithium (LiV₂O₅), magnesium silicate (Mg₂SiO₄), magnesium silicate (MgSiO₃), titanic acid zirconium (ZrTiO₄), strontium titanate (SrTiO₃), magnesium acid plumbum (PbMgO₃), lead niobate (PbNbO₃), barium borate (BaB₂O₄), chromic acid lanthanum (LaCrO₃), lithium titanate (LiTi₂O₄), cuprate lanthanum (LaCuO₄), titanic acid zinc (ZnTiO₃) and calcium tungstate (CaWO₄) are exemplified.

In addition, for metal used here, metal simple substance or an alloy of cesium (Cs), chromium (Cr), molybdenum (Mo), tungsten (W), rhenium (Re), iron (Fe), ruthenium (Ru), osmium (Os), rhodium (Rh), iridium (Ir), nickel (Ni), palladium (Pd), platinum (Pt), silver (Ag), gold (Au), silicon (Si), Ge, antimony (Sb), selenium (Se) and tellurium (Te) is exemplified.(work function of above mentioned metals: 4.5-5.5 eV)

In addition, a metal unit or alloys such as vanadium (V), niobium (Nb), tantalum (Ta), titanium (Ti), zirconium (Zr), hafnium (HO, scandium (Sc), yttrium (lateral), thorium (Tr), manganese (Mn), cobalt (Co), copper (Cu), zinc (Zn), cadmium (Cd), aluminium (Al), gallium (Ga), indium (In), tin (Sn), plumbum (Pb), bismuth (Bi) or so-called rare-earth element from lanthanum (La) to lutetium (Lu) are exemplified.

It is preferable for thickness of this ion blocking barrier layer 5 to be equal to or less than 10 nm when optical transparency is necessary.

In addition, when an inorganic material having high insulating properties is used, it is preferable for the inorganic material thickness to be lower than 10 nm so that tunneling current flows. In addition, it is more preferable for thickness of an inorganic material to be 1-5 nm.

In addition, when an inorganic material having high conductivity like metal is used, it is desirable that a work function of an inorganic material is at the same level as a work function of each layer so that charge injection from organic hole injection layer 4 to organic luminescent layer 7, a hole transport layer or electron blocking layers is performed smoothly. For example, it is preferable for a work function of an inorganic material to be 4.5-5.5 eV.

When an inorganic material, especially a metal, touches an exciton of organic luminescent layer 7, quenching occurs. Therefore an organic layer such as a hole transport layer and electron blocking layer had better be placed between ion blocking barrier layer 5 and organic luminescent layer 7. But when a luminescent part in an organic luminescent layer is near to the cathode, it is not necessary to install these layers.

Hole transport layer and electronic blocking layer 6 is a layer having a material having hole transport characteristics and/or electron block characteristics.

Each layer has the following roles: A barrier of hole injection from ion blocking barrier layer 5 to organic luminescent layer 7 is lowered; Hole injected from transparent first electrode layer 2 is advanced towards cathode layers 9; and While passing hole, electron advancing towards the first transparent electrode layer 2 through organic luminescent layer 7 is disturbed.

For material used for these layers, material generally employed as a hole transport material can be used.

For example, the following materials can be used: copper phthalocyanine and the derivative; Low molecular such as aromatic amine system such as 1,1-bis (4-di-p-tolylamino phenyl) cyclohexane, N,N′-diphenyl-N,N′-bis (3-methylphenyl)-1,1′-biphenyl-4,4′-diamine, N,N′-di(l-naphthyl)-N,N′-diphenyl-1,1′-biphenyl-4,4′-diamine; Polymeric material such as poly thiophenes, polyvinyl carbazole derivative or polyvinyl pyridine derivative; and the material which low-molecular material showing hole transport characteristics and electron block characteristics such as aryl amines, carbazoles, aryl sulfide, thiophenes or phthalocyanines mixes with an electroconductive polymer such as poly arylene system such as polyparaphenylene (PPP) or PAV [polyarylenevinylene] system such as polyphenylene vinylene (PPV) or polymers such as polystyrene (PS).

Organic luminescent layer 7 is the material layer having luminosity.

For a luminous body used for this organic luminescent layer 7, low molecular luminosity coloring matter such as coumarin system, perylene system, a pyran system, anthrone system, a porphyrin system, quinacridon system, N,N′-dialkyl permutation quinacridon system, naphthalimido system, N,N′-diaryl permutation pyrrolo pyrrole series, iridium complex system, platinum complex system or europium complex system can be illustrated.

In addition, the material which the above mentioned material dissolves in polymers such as PS, polymethyl methacrylate or polyvinyl carbazole can be used.

In addition, polymer luminous bodies such as poly arylene system, PAV [polyarylenevinylene] system or poly fluorene system can be used.

Hole blocking layer and electron transport layer are layers having a material having electron transport property and/or hole block characteristics.

Each layer has the following roles: An electron injected from cathode layers 9 is advanced towards transparent first electrode layer 2; and while passing electron, hole advancing towards cathode layers 9 is disturbed.

For material used for these layers, material of low molecular system such as a charge transfer complex of 7,7,8,8-TCNQ [tetracyano-quinodimethane] (TCNQ) derivatives, a silole derivative, an aryl boron derivative, pyridines such as bis phenanthroline, perfluorinated olig-phenylene derivative or oxadiazoles can be illustrated.

From the viewpoint of film formation property, a material having electron transport property such as electron transport property poly silane, poly silole and polymer including boron is desirable.

In addition, the material which aforementioned material having electron transport property or hole block property mixes with an electroconductive polymer such as poly arylene system such as PPP or PAV [polyarylenevinylene] system such as PPV or polymers such as polystyrene may be used.

Electron injection layer 8 is a layer having electron injection property material. Electron injection layer 8 lowers electronic injection barriers from cathode layer 9 as the second electrode to organic luminescent medium layer 3.

For a material of the electron injection layer, aforementioned material used for the electron transport layer can be used. The material which alkali metal such as lithium fluoride or lithium oxide and salt and oxide of alkaline earth metals mix with polymeric material such as PS may be further used.

For formation of these layers, the following method can be used: Dry method such as a vacuum evaporation method, CVD method and a sputtering method; wet method such as coating or a printing method such as a spin coat method, a curtain coat method, a bar coat method, a wire coat method, a slit coat method, letterpress printing, intaglio printing, screen printing, gravure printing, flexographic printing method and offset printing.

Besides, all methods that do not lose performance of organic luminescent medium layer 3 can be utilized.

In addition, when these layers are made by a wet method, the following material can be used for a solvent dissolving these materials: The material which substituent is introduced into aromatic rings of toluene, xylene, mesitylene, anisole, monochlorobenzene, p-cymene, diethylbenzene, cyclohexylbenzene, detergent alkylate or the like; and acetone, methyl ethyl ketone, methyl isobutyl ketone, cyclopentanone, cyclohexanone, methanol, ethanol, isopropanol, ethyl acetate, butyl acetate, water. Mixed solvent comprising these solvents can be used if necessary.

In addition, a surface active agent, an antioxidant, a viscosity modifier or ultraviolet absorber may be added in a solvent if necessary.

After formation of organic luminescent medium layer 3, cathode layer 9 as the second electrode is formed.

The following material can be used for cathode layer 9 as the second electrode: Metal simple substance such as Mg, Al or Yb can be used; Li and chemical compound such as LiF of around 1 nm thickness are placed in a surface boundary of a luminescent medium material, and Al and the Cu of which stability/conductivity is high can be laminated; and alloy system of the low work function metal and the stable metal of which both electron injection efficiency and stability are high can be used.(alloys such as MgAg, AlLi or CuLi.)

As for the formation method of a cathode, depending on the material, a resistance heating vapor deposition method, an eletron beam method and a sputtering method can be used.

As for the thickness of a cathode, about 10 nm-1,000 nm are desirable.

Finally a glass cap and adhesive are used, and an organic electroluminescent element is sealed to protect the organic electroluminescent from outside oxygen and moisture. An organic electroluminescent element can be obtained in this way. In addition, when a transparent substrate is flexibility, an organic electroluminescent element is sealed using a sealing compound and a flex film.

### EXAMPLE 1

A glass substrate was used as a substrate. The thickness of a glass substrate was 0.7 mm. The diagonal length of a glass substrate was 1.8 inches.

ITO film was formed on this substrate by a sputter method in vacuum using ITO which is an anode material.

A line electrode was formed by patterning ITO film by photo-lithography method and etching using an acid solution.

The pattern of a line electrode was the following line pattern: the line width was 136 μm; the space was 30 μm; the number of lines was 192.

Next acrylic photoresist material as an insulator layer material was applied to a whole area of the glass substrate on which a line electrode was formed by a spin coat. The spin coat was performed under the following condition: At first it spun at 150 rpm for 5 seconds; and next, it spun at 500 rpm for 20 seconds.

The coated film of which thickness was 1.5 μm was obtained.

By photo-lithography method, a line-shaped insulator layer was formed between electrodes afterwards.

Polyethylen dihydroxy thiophen (PEDOT) 1 wt % liquid was used as hole injection layer ink next. Using this PEDOT liquid, a hole injection layer was formed on a line electrode between insulator layers by letterpress printing in atmospheric air. In this time, an anilox roll of 180 line/inch and water-developable photosensitive resin plate were used. The hole injection layer of which thickness after drying was 50 nm was formed in this way.

Next triphenylamines which was a hole transport material was dissolved in cyclohexanol so that the concentration of triphenylamines was 1 wt %. Using this ink, a hole transport layer was formed on the hole injection layer by letterpress printing in atmospheric air. In this time, an anilox roll of 150 line/inch and water-developable photosensitive resin plate were used. The hole transport layer of which thickness after drying was 30 nm was formed.

Organic luminescent material ink was made next. The concentration of the PPV derivative which was an organic luminescent material was 1 wt %. The concentration of xylene and anisole was 84 wt % and 15 wt % respectively.

Using this ink, an organic luminescent layer was formed on a hole transport layer by letterpress printing in atmospheric air. In this time, an anilox roll of 200 line/inch and water-developable photosensitive resin plate were used.

The organic luminescent layer of which thickness after drying was 80 nm was formed.

Next SiOₓ barrier layer of which thickness was 0.4 nm was formed on an organic luminescent layer by plasma CVD technique in vacuum using SiH₄ and O₂ and using a mask.

Next, on a barrier layer, a mask is used, the electron injection layer of which thickness was 5 nm was formed by a vacuum evaporation method using a mask and using Ca which was an electron injection material.

Finally, a cathode of the following line pattern was formed by a vacuum evaporation method using Al which was a cathode material and using a mask so that a cathode was perpendicular to an anode of ITO: The thickness of a line pattern was 150 nm; the line width of a line pattern was 136 μm; the space was 30 μm; and the number of lines was 192.

And an organic electroluminescent element was sealed using a glass cap and adhesive.

Display unit comprising an organic electroluminescent element of passive matrix type was obtained in this way.

Luminescent property of an obtained display unit comprising an organic electroluminescent element of passive matrix type was evaluated.

There was not a short-circuit between electrodes. Only a selected picture element was able to be lighted. Light was emitted uniformly without unevenness. Luminance was 160 cd/m² at 6V.

In addition, initial luminance was 400 cd/m², and half life of luminance was 1600 hours.

In other words, a good display characteristic of high luminous efficiency, high emission brightness and long life was obtained.

### EXAMPLE 2

Display unit comprising an organic electroluminescent element of passive matrix type was made by replacing a barrier layer of example 1 with SiNₓ.

The barrier layer of SiNₓ was formed using SiH₄ and N₂ by a vacuum evaporation method. The barrier layer thickness was 0.4 nm.

Luminescent property of obtained display unit was evaluated.

There was not a short-circuit between electrodes. Only a selected picture element was able to be lighted. Light was emitted uniformly without unevenness. Luminance was 170 cd/m² at 6V.

In addition, initial luminance was 400 cd/m², and half life of luminance was 1700 hours.

In other words a good display characteristic of high luminous efficiency, high emission brightness and long life was obtained.

### EXAMPLE 3

Display unit comprising an organic electroluminescent element of passive matrix type was made by replacing a barrier layer of example 1 with AlF₃. The barrier layer of AlF₃ was made by a vacuum evaporation method. The barrier layer thickness was 0.4 nm.

Luminescent property of obtained display unit was evaluated.

There was not a short-circuit between electrodes. Only a selected picture element was able to be lighted. Light was emitted uniformly without unevenness. Luminance was 175 cd/m² at 6V.

In addition, initial luminance was 400 cd/m², and half life of luminance was 1600 hours.

In other words a good display characteristic of high luminous efficiency, high emission brightness and long life was obtained.

### EXAMPLE 4

Display unit comprising an organic electroluminescent element of passive matrix type was made by replacing a barrier layer of example 1 with Pd. The barrier layer of Pd was formed by an eletron beam method. The barrier layer thickness was 0.4 nm.

Luminescent property of obtained display unit was evaluated.

There was not a short-circuit between electrodes. Only a selected picture element was able to be lighted. Light was emitted uniformly without unevenness. Luminance was 200 cd/m² at 6V.

In addition, initial luminance was 400 cd/m², and the half life of luminance was 2000 hours.

In other words a good display characteristic of high luminous efficiency, high emission brightness and long life was obtained.

### EXAMPLE 5

A glass substrate with ITO was prepared. ITO was etched so that ITO of predetermined pattern is formed. Subsequently, water dispersions of PEDOT-PSS was applied on the etched transparent first electrode layer by a spin coat method. This substrate was dried in an atmospheric air at 200 degrees Celsius for three minutes. Then organic hole injection layer 4 was obtained. The thickness of organic hole injection layer 4 after drying was 50 nm.

Platinum film of predetermined pattern was formed on this organic hole injection layer 4 by a vacuum evaporation method. Ion blocking barrier layer 5 was obtained in this way. The film thickness of ion blocking barrier layer 5 was 5 nm.

By a spin coat method, cyclohexanol solution including a polythiophene derivative was applied to ion blocking barrier layer 5. And this substrate was dried in a pressure reduced oven of 140 degrees Celsius for one hour. Hole transport layer 6 was obtained in this way. The film thickness was 10 nm.

In addition, toluene solution including poly (2-(2-ethyl hexyloxy methoxy)-5-methoxy-1,4-phenylenevinylene) which was a macromolecular luminous body of PAV [polyarylenevinylene] system was applied on hole transport layer 6 by a spin coat method. This substrate was dried in a pressure reduced oven of 140 degrees Celsius for one hour. Organic luminescent layer 7 was obtained in this way. The film thickness of organic luminescent layer 7 was 70 nm.

Lithium fluoride (thickness: 0.5 nm) and aluminium (thickness: 200 nm) were further provided by vacuum deposition respectively. Electron injection layer 8 and cathode 9 was obtained in this way.

An organic electroluminescent element emitted light in the shape of pattern (100 cd/m²) when voltage of 8V was applied to an obtained organic electroluminescent element.

In addition, initial luminance was 100 cd/m², and half life of luminance in case of a constant current drive was measured. The luminance half time was 3000 hr.

In addition, an organic electroluminescent element after a fifty percent reduction of luminance was analyzed by TOF-SIMS (Time Of Fright-Secondary Ion Mass Spectroscopy) method. The component which came from a sulfate ion was not found in the organic electroluminescent layer near a cathode.

### COMPARATIVE EXAMPLE 1

A display unit comprising an organic electroluminescent element of passive matrix type was made without providing a barrier layer of SiOₓ of example 1.

In obtained display unit, there was not a short-circuit between electrodes. Only a selected picture element was able to be lighted. However, luminescent unevenness was recognized. In addition, the luminance was 120 cd/m² at 6V.

Initial luminance was 400 cd/m², and half life of luminance was 800 hours.

As compared to an organic electroluminescent element of example 1 having a barrier layer, the display characteristic of low luminous efficiency, low emission brightness and a short life time was obtained.

### REFERENCE EXAMPLE 1

In example 1, display unit comprising an organic electroluminescent element of the passive matrix type of which barrier layer thickness of SiOₓ was 0.05 nm was made.

In obtained display unit, there was not a short-circuit between electrodes. Only a selected picture element was able to be lighted. However, a barrier effect was not obtained sufficiently. Luminescent unevenness was recognized. In addition, the luminance was 140 cd/m² at 6V.

Initial luminance was 400 cd/m², and half life of luminance was 1000 hours.

As compared to example 1, a display characteristic of low luminous efficiency, low emission brightness and short life time was obtained.

### REFERENCE EXAMPLE 2

In example 1, a display unit comprising an organic electroluminescent element of the passive matrix type of which a barrier layer thickness of SiOₓ was 1.5 nm was made.

In the obtained display unit, there was not a short-circuit between electrodes. Only a selected picture element lighted. There was no unevenness, and it emitted light uniformly. However, the luminance was 130 cd/m² at 6V because electron transfer was disturbed.

Initial luminance was 400 cd/m², and half life of luminance was 1100 hours. As compared with example 1, the display characteristic of low luminous efficiency, low emission brightness and short life time was obtained.

### COMPARATIVE EXAMPLE 2

An organic electroluminescent element of example 5 which did not have an ion blocking barrier layer was made. It emitted light in the shape of pattern when a voltage of 12V was applied to an obtained electroluminescent device (100 cd/m²).

In addition, initial luminance was 100 cd/m², and luminance half life in case of a constant current drive was measured. The luminance half life was 300 hr.

An organic electroluminescent element after a fifty percent reduction of luminance was analyzed by the TOF-SIMS method. The component which came from a sulfate ion was found in the organic electroluminescent layer near a cathode.

As for this phenomenon, it is believed as follows: These component is the component that the ion component which occurred by electrolysis of PEDOT-PSS scattered in an organic film; and these components are impurities mixed in an organic luminescent layer.

What is claimed is:

1. An organic electroluminescent element comprising a first electrode, a second electrode, an organic luminescent medium layer including an organic luminescent layer and an inorganic barrier layer,
wherein the first electrode faces the second electrode,
wherein the organic luminescent medium layer is between the first electrode and the second electrode,
and wherein the inorganic barrier layer is contained with the organic luminescent medium layer.

2. The organic electroluminescent element according to claim 1,
wherein the inorganic barrier layer comprises an insulating material or a semi-conductor comprising oxide, nitride and fluoride, or a metal having a work function that is equal to or more than 4.0 eV.

3. The organic electroluminescent element according to claim 1,
wherein the thickness of the inorganic barrier layer is 0.1 nm-1.0 nm.

4. The organic electroluminescent element according to claim 1,
wherein the organic luminescent medium layer includes an electron injection layer.

5. A manufacturing method for an organic electroluminescent element including a first electrode, a second electrode, an organic luminescent medium layer including an organic luminescent layer,
wherein the first electrode faces the second electrode,
wherein the organic luminescent medium layer is between the first electrode and the second electrode,
said method comprising forming an organic luminescent medium layer on the first electrode in atmospheric air,
next forming a barrier layer, and
next forming another organic luminescent medium layer in vacuum condition.

6. The manufacturing method of an organic electroluminescent element according to claim 5,
wherein the barrier layer is an inorganic barrier layer.

7. The manufacturing method of an organic electroluminescent element according to claim 5,
wherein the barrier layer comprises an insulating material or a semi-conductor comprising oxide, nitride and fluoride, or a metal having a work function that is equal to or more than 4.0 eV.

8. The manufacturing method of an organic electroluminescent element according to claim 5,
wherein the thickness of the barrier layer is 0.1 nm-1.0 nm.

9. The manufacturing method of an organic electroluminescent element according to claim 5,
whrein forming an organic luminescent medium layer on the first electrode in atmospheric air is performed by letterpress printing.

10. The manufacturing method of an organic electroluminescent element according to claim 5,
wherein the another organic luminescent medium layer is an electron injection layer.

11. An organic electroluminescent element manufactured by the method according to claim 5.

12. A display having an organic electroluminescent element according to claim 1 as a display device.

13. A display having an organic electroluminescent element according to claim 11 as a display device.

14. An organic electroluminescent element comprising a transparent first electrode, a second electrode facing the first electrode, an organic luminescent medium layer including an organic charge injection layer, an organic luminescent layer between the first electrode and the second electrode, and an ion blocking barrier layer,
wherein the ion blocking barrier layer includes an inorganic material and is disposed between the organic charge injection layer and the organic luminescent layer.

15. An organic electroluminescent element according to claim 14,
wherein the organic charge injection layer includes an ionic material.

16. An organic electroluminescent element according to claim 14, wherein the organic charge injection layer comprises a mixture of poly (3,4-ethylenedioxy thiophen) and polystyrene sulfonate (PEDOT-PSS) or Polyaniline (PANI), to which an ionic dopant is added.

17. An organic electroluminescent element according to claim 14,
wherein the thickness of the ion blocking barrier layer is equal to or less than 10 nm.

18. An organic electroluminescent element according to claim 14,
wherein the organic charge injection layer is a hole injection layer.

19. An organic electroluminescent element according to claim 14,
wherein a work function of the inorganic material included in the ion blocking barrier layer is 4.5-5.5 eV.4
